(19) United States
(12) Patent Application Publication
(10) Pub. No.: US 2026/0059655 A1
(43) Pub. Date: Feb. 26, 2026

(54) PRINTED CIRCUIT BOARD

(71) Applicant: SAMSUNG ELECTRO-MECHANICS CO., LTD., Suwon-si (KR)

(72) Inventor: Woo Sam Choi, Suwon-si (KR)

(73) Assignee: SAMSUNG ELECTRO-MECHANICS CO., LTD., Suwon-si (KR)

(21) Appl. No.: 19/235,461

(22) Filed: Jun. 11, 2025

(30) Foreign Application Priority Data
Aug. 26, 2024 (KR) 10-2024-0114402

(51) Int. Cl. H05K 1/02; H05K 1/03; H05K 1/11

(52) U.S. Cl. CPC H05K 1/0271; H05K 1/0298; H05K 1/0306; H05K 1/115; H05K 2201/09827

(57) ABSTRACT

A printed circuit board includes a glass layer; a first insulating layer covering each of an upper surface and a lower surface of the glass layer; a first conductor layer disposed on an upper surface of the first insulating layer; a second conductor layer disposed on a lower surface of the first insulating layer; and a through-hole penetrating between the first and second conductor layers, and a through-via including a via conductor disposed in the through-hole and connected to the first and second conductor layers, wherein a wall surface of the through-hole has at least one shifted region.

### CROSS-REFERENCE TO RELATED APPLICATIONS

This application claims benefit of priority to Korean Patent Application No. 10-2024-0114402 filed on Aug. 26, 2024 in the Korean Intellectual Property Office, the disclosure of which is incorporated herein by reference in its entirety.

### BACKGROUND

### 1. FILLED

The present disclosure relates to a printed circuit board.

### 2. DESCRIPTION OF RELATED ART

Recently, in order to improve performance of a printed circuit board, large area, a highly multilayer structure, and miniaturization may be necessary. Copper clad laminate (CCL) may be used as a core layer included in a printed circuit board, but warpage may easily occur due to a low modulus and high coefficient of thermal expansion, and there may be limitations in implementing a microcircuit. Accordingly, a core layer formed of a new material which may suppress warpage and facilitate implementation of a microcircuit has been necessary. Also, a printed circuit board which may reduce the number of processes and may reduce costs while using a core layer formed of a new material, and may secure stability of process may be necessary.

### SUMMARY

An aspect of the present disclosure is to provide a printed circuit board which may be advantageous for warpage control and may easily implement a microcircuit therein.

An aspect of the present disclosure is to provide a printed circuit board which may reduce the number of processes and costs.

An aspect of the present disclosure is to provide a printed circuit board which may assure process stability and a through-via therein may have improved reliability.

An aspect of the present disclosure is to embed a glass layer in an insulating layer as a core layer by laminating the insulating layer on the glass layer, to form a through-hole through a single process after embedding the glass layer, to form a through-via by filling the through-hole with a conductor, and to form at least one shifted region on a wall surface of a through-hole when the through-hole is formed.

According to an example embodiment, a printed circuit board includes a glass layer; a first insulating layer covering each of an upper surface and a lower surface of the glass layer; a first conductor layer disposed on an upper surface of the first insulating layer; a second conductor layer disposed on a lower surface of the first insulating layer; and a through-hole penetrating between the first and second conductor layers, and a through-via including a via conductor disposed in the through-hole and connected to the first and second conductor layers, wherein a wall surface of the through-hole has at least one shifted region.

According to an example embodiment, a printed circuit board includes an insulating layer; a glass layer embedded in the insulating layer; a first conductor layer disposed on an upper surface of the insulating layer; a second conductor layer disposed on a lower surface of the insulating layer; and a through-via penetrating the insulating layer and the glass layer between the first and second conductor layers and connecting the first and second conductor layers to each other, wherein a side surface of the through-via has at least one shifted region.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an example of an electronic device system;

FIG. 2 is a perspective diagram illustrating an example of an electronic device;

FIG. 3 is a cross-sectional diagram illustrating an example of a printed circuit board according an example embodiment;

FIGS. 4A, 4B, 4C, 4D, 4E, 4F, 4G, and 4H are enlarged cross-sectional diagrams illustrating various examples of a through-via formed in region A of the printed circuit board illustrated in FIG. 3;

FIG. 5 is a cross-sectional diagram illustrating another example of a printed circuit board according an example embodiment; and

FIGS. 6A, 6B, 6C, 6D, 6E, 6F, 6G, and 6H are cross-sectional diagrams illustrating various examples of a through-via formed in region B of the printed circuit board illustrated in FIG. 5.

### DETAILED DESCRIPTION

Hereinafter, embodiments of the present disclosure will be described as follows with reference to the attached drawings. Some elements may be exaggerated, omitted or briefly illustrated, and the sizes of the elements do not necessarily reflect the actual sizes of these elements

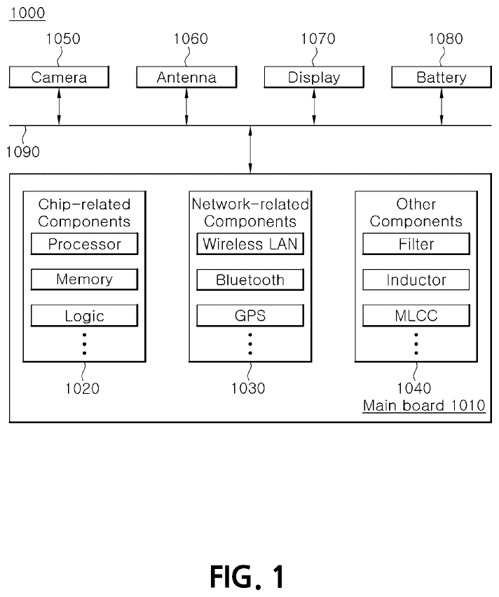

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

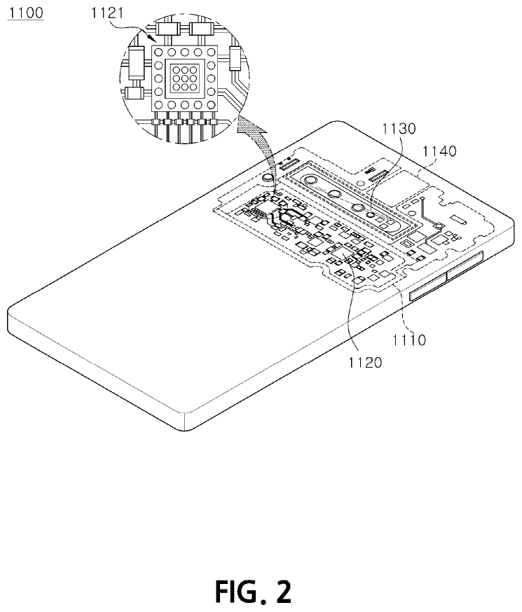

FIG. 2 is a perspective diagram illustrating an example of an electronic device.

Referring to FIG. 2, an electronic device may be a smartphone 1100, for example. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment example thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above. Also, the electronic device may be a server-related product to which a large-area substrate is required.

### Printed Circuit Board

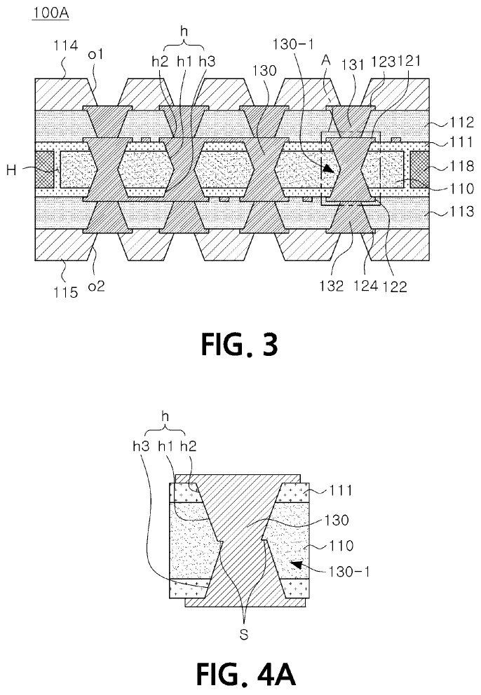

FIG. 3 is a cross-sectional diagram illustrating an example of a printed circuit board according an example embodiment.

Referring to the drawings, a printed circuit board 100A according to an example may include a glass layer 110, a first insulating layer 111 covering each of an upper surface and a lower surface of the glass layer 110, a first conductor layer 121 disposed on the upper surface of the first insulating layer 111, a second conductor layer 122 disposed on the lower surface of the first insulating layer 111, and a through-hole h penetrating the first insulating layer 111 and/or the glass layer 110 between the first and second conductor layers 121 and 122, and a through-via 130-1 including a via conductor 130 disposed in the through-hole h and connected to the first and second conductor layers 121 and 122. The through-hole h may penetrate the first insulating layer 111 and the glass layer 110 together. For example, the through-hole h may include a first portion h1 penetrating the glass layer 110, a second portion h2 penetrating a region of the first insulating layer 111 covering an upper surface of the glass layer 110, and a third portion h3 penetrating a region of the first insulating layer 111 covering a lower surface of the glass layer 110. At least a portion of the via conductor 130, for example, a portion of the via conductor 130 disposed in the first portion h1, may be in contact with the glass layer 110. At least the other portion of the via conductor 130, for example, the other portion of the via conductor 130 disposed in the second and third portions h2 and h3, may be in contact with the first insulating layer 111.

Since the printed circuit board 100A includes the glass layer 110 as described above, warpage control may be easily performed, and a microcircuit may be easily implemented. Also, by covering the glass layer 110 with the first insulating layer 111, processing a through-hole h penetrating the layers at once by drilling, and forming a through-via 130-1 including the first and second conductor layers 121 and 122 and the via conductor 130 connecting the layers by a plating process, the number of processes and costs may be reduced. Also, reliability of the through-via 130-1 may be more excellent than a stack via. Also, a minimum pitch of the through-via 130-1 may be easily implemented.

The glass layer 110 may be embedded in the first insulating layer 111. For example, the first insulating layer 111 may cover an upper surface and a lower surface of the glass layer 110, and also a side surface of the glass layer 110. Accordingly, the glass layer 110 may function as a core layer. Accordingly, the above-described technical effects may be implemented easily. Also, breakage of the glass layer 110 may be effectively prevented.

If desired, the printed circuit board 100A may further include a frame 118 having a through-portion h. The glass layer 110 may be disposed at least a portion in the through-portion h. The first insulating layer 111 may further cover an upper surface and a lower surface of the frame 118, and may fill at least a portion of the through-portion h. For example, the layer may fill at least a portion between a side surface of the frame 118 and a side surface of the glass layer 110. Warpage control may be easily performed through the frame 118, and process handling may become easier. Also, the plurality of through-portions h may be formed in the frame 118 having a large area, and accordingly, a plurality of printed circuit boards 100A may be manufactured through the same process, and may be divided and manufactured by a cutting process, such that productivity may be increased.

If desired, the printed circuit board 100A may be disposed on the upper surface of the first insulating layer 111, the second insulating layer 112 covering at least a portion of the first conductor layer 121, the third insulating layer 113 covering at least a portion of the second conductor layer 122 disposed on the lower surface of the first insulating layer 111, the third conductor layer 123 disposed on the upper surface of the second insulating layer 112, the fourth conductor layer 124 disposed on the lower surface of the third insulating layer 113, the first connection via 131 penetrating at least a portion of the second insulating layer 112 and connecting at least a portion of each of the first and third conductor layers 121 and 123, the second connection via 132 penetrating at least a portion of the third insulating layer 113 and connecting at least a portion of each of the second and fourth conductor layers 122 and 124, and the second connection via 132 disposed on the upper surface of the second insulating layer 112 and connecting at least a portion of each of the second and fourth conductor layers 122 and 124. A first passivation layer 114 having a plurality of first openings o1, each exposing at least a portion of the first passivation layer 114, and/or a second passivation layer 114 disposed on a lower surface of the third insulating layer 113 and having a plurality of second openings o2, each exposing at least a portion of the fourth conductor layer 124, may further include. For example, the printed circuit board 100A may have a multilayer structure, and may thus be used as an flip-chip board (FCB), ball grid array (BGA), an interposer substrate, a package substrate, or the like. However, an embodiment thereof is not limited thereto, and the embodiment may be applied to various other types of substrates.

Hereinafter, components of the printed circuit board 100A according to an example will be described in greater detail with reference to the drawings.

The glass layer 110 may include glass, which is an amorphous solid. The glass may include, for example, pure silicon dioxide (about 100% SiO₂), soda-lime glass, borosilicate glass, aluminosilicate glass, or the like. However, an embodiment thereof is not limited thereto, and alternative glass materials, for example, fluoride glass, phosphate glass, chalcogenide glass, or the like, may also be used as a material thereof. Also, other additives may be further included to form a glass having specific physical properties. Such additives may include calcium carbonate (e.g., lime) and sodium carbonate (e.g., soda), as well as magnesium, calcium, manganese, aluminum, lead, boron, iron, chromium, potassium, sulfur antimony, and carbonates and/or oxides of these elements and other elements. The glass layer 110 may be distinct from organic insulating materials including glass fiber (glass cloth, glass fabric), such as copper clad laminate (CCL), prepreg (PPG), or the like. For example, the glass layer 110 may include a glass panel formed in a relatively large area, such as a glass plate.

Each of the first to third insulating layers 111, 112, and 113 and the first and second resist layers 114 and 115 may include an organic insulating material. The organic insulating material may include a thermosetting resin such as an epoxy resin, a thermoplastic resin such as a polyimide, or a resin together with an inorganic filler, an organic filler and/or glass fiber (glass cloth, glass fabric). For example, the organic insulating material may be prepreg (PPG), Ajinomoto build-up film (ABF), photoimageable dielectric (PID), solder resist (SR), or the like, but an embodiment thereof is not limited thereto. If desired, each of the first to third insulating layers 111, 112, and 113 and the first and second resist layers 114 and 115 may include a plurality of layers. The first and second resist layers 114 and 115 may have first and second openings o1 and o2, respectively, and a plurality of the first and second openings o1 and o2 may be provided. The pad patterns of the third and fourth conductor layers 123 and 124 exposed through the first and second openings o1 and o2 may be in the form of solder mask defined (SMD) and/or non-solder mask defined (NSMD).

The frame 118 may include various materials. For example, the frame 118 may include an organic insulating material of copper clad laminate (CCL), or may include an inorganic insulating material such as silicon or ceramic, or may include a metal plate including copper (Cu), or the like. However, an embodiment thereof is not limited thereto. The frame 118 may have a through-portion h. The through-portion h may penetrate between the upper surface and the lower surface of the frame 118. The through-portion h may have a shape substantially corresponding to the glass layer 110. The through-portion h may continuously surround the side surface of the glass layer 110. For example, the through-portion h may have an approximately rectangular shape on the plane. If desired, the frame 118 may include a plurality of units spaced apart from each other, the number of which may not limited to any particular example.

Each of the first to fourth conductor layers 121, 122, 123, and 124 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment thereof is not limited thereto. The first to fourth conductor layers 121, 122, 123, and 124 may perform various functions depending on a design. For example, the layers may include a signal pattern, a power pattern, and a ground pattern. These patterns may have various shapes such as a line, a plane, and a pad, respectively. Each of the first to fourth conductor layers 121, 122, 123, and 124 may include a seed layer and a plating layer. The seed layer may be formed by electroless plating (e.g., chemical copper) or, if desired, by a sputtering process. Alternatively, both may be used. The plating layer may be formed by electrolytic plating (e.g., electrolytic copper). The first to fourth conductor layers 121, 122, 123, and 124 may be formed by a plurality of layers corresponding to the first to third insulating layers 111, 112, and 113, respectively. The first to fourth conductor layers 121, 122, 123, and 124 may protrude on the first to third insulating layers 111, 112, and 113, but may also be embedded in the first to third insulating layers 111, 112, and 113.

The through-via 130-1 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment thereof is not limited thereto. The through-via 130-1 may include a via conductor 130 filling at least a portion of the through-hole h. The via conductor 130 may perform various functions depending on a design. For example, the via conductor 130 may include a signal via, a power via, a ground via, or the like. The via conductor 130 may be connected to each of the first and second conductor layers 121 and 122. The through-hole h and the via conductor 130 filling the through-hole h may have a cross-section having an hourglass shape in which a width at an upper end connected to the first conductor layer 121 and a width at a lower end connected to the second conductor layer 122 are greater than a width at a central portion on a cross-section cutting the through-hole h in the thickness direction. The central portion of the through-hole h may be disposed between the upper surface and the lower surface of the glass layer 110. The via conductor 130 may include a seed layer and a plating layer. The seed layer may be formed by electroless plating (e.g., chemical copper) or, if desired, by a sputtering process. Alternatively, both may be used. The plating layer may be formed by electrolytic plating (e.g., electrolytic copper). When a plurality of the through-holes h are provided, also a plurality of the via conductor 130 may be provided.

Each of the first and second connection vias 131 and 132 may include a metal. The metal may include copper (Cu), aluminum (Al), silver (Ag), tin (Sn), gold (Au), nickel (Ni), lead (Pb), titanium (Ti), and/or alloys thereof. Preferably, copper (Cu) may be included, but an embodiment thereof is not limited thereto. Each of the first and second connection vias 131 and 132 may perform various functions depending on a design. For example, the vias may include a signal via, a power via, a ground via, or the like. Each of the first and second connection vias 131 and 132 may include a filled via in which the via hole is filled with a metal, and may also include a conformal via in which the metal is disposed along a wall surface of the via hole, if desired. Each of the first and second connections via 131 and 132 may have a tapered shape on a cross-section. For example, a width of an upper end of the first connection via 131 may be greater than a width of a lower end on a cross-section, and a width of an upper end of the second connection via 132 may be greater than a width of a lower end in the cross-section. Both the first and second connections via 131 and 132 may include a seed layer and a plating layer included in the third and fourth conductor layers 123 and 124, respectively. A plurality of the first and second connections via 131 and 132 may be provided.

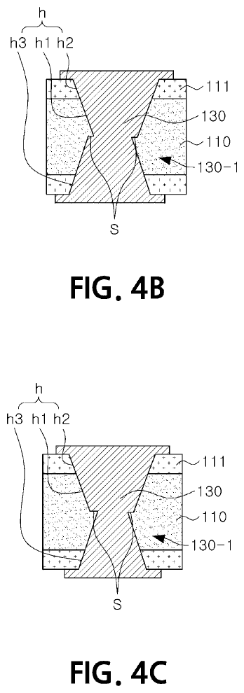

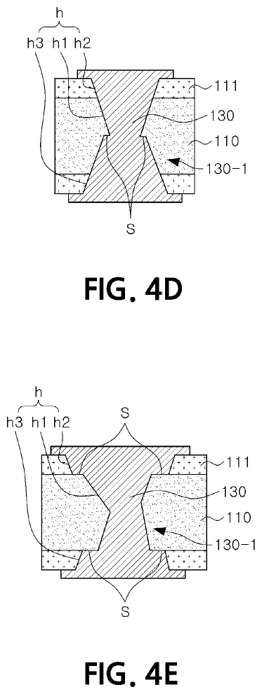

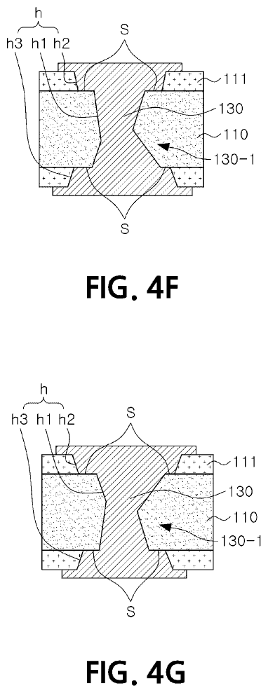

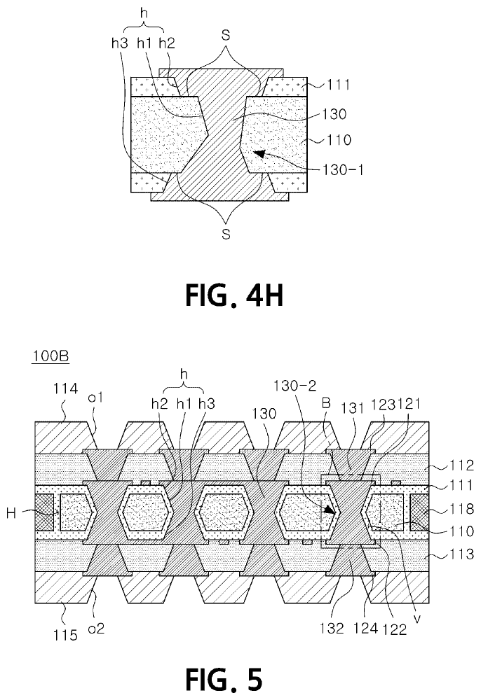

FIGS. 4A to 4H are enlarged cross-sectional diagrams illustrating various examples of a through-via formed in region A of the printed circuit board illustrated in FIG. 3.

Referring to FIGS. 4A to 4D, a wall surface of the through-hole h may have at least one shifted region S. In this view, a side surface of the through-via 130-1 may have at least one shifted region S. For example, as in FIGS. 4A to 4D, on a cross-section cutting the through-hole h in the thickness direction, the wall surface of the through-hole h may have at least one shifted region S at substantially the same level as the central portion of the through-hole h with respect to the thickness direction. Specifically, the through-via 130-1 may include at least two via portions having a taper shape in opposite directions and connected to each other. In FIG. 4A, a lower via portion of the two via portions may be shifted to the right with respect to an upper via portion of the two via portions, such that a lower end of the upper via portion and an upper end of the lower via portion are misaligned with each other at the at least one shifted region S. A width at the lower end of the upper via portion may be substantially the same as a width at the upper end of the lower via portion. In FIG. 4B, the lower via portion of the two via portions may be shifted to the left with respect to the upper via portion of the two via portions, such that the lower end of the upper via portion and the upper end of the lower via portion are misaligned with each other at the at least one shifted region S. The width at the lower end of the upper via portion may be substantially the same as the width at the upper end of the lower via portion. In FIG. 4C, left and right edges of the upper end of the lower via portion may be shifted towards a center portion thereof with respect to left and right edges of the lower end of the upper via portion, respectively. As such, the width at the lower end of the upper via portion may be smaller than the width at the upper end of the lower via portion. In FIG. 4D, the left and right edges of the upper end of the lower via portion may be shifted away from the center portion thereof with respect to the left and right edges of the lower end of the upper via portion, respectively. As such, the width at the lower end of the upper via portion may be larger than the width at the upper end of the lower via portion.

As in FIGS. 4E to 4H, on a cross-section cutting the through-hole h in the thickness direction, the wall surface of the through-hole h may have at least one shifted region S at substantially the same level as each of the boundaries between the upper surface and the lower surface of the glass layer 110 and the first insulating layer 111 with respect to the thickness direction. As in FIGS. 4E to 4H, in the cross-section cutting through-hole h in the thickness direction, the wall surface of the through-hole h may have a plurality of internal walls having different slopes. For example, the first portion h1 of the wall surface of the through-hole h may have four internal walls having different slopes. In this case, an inflection point between the two internal walls on the left side and an inflection point between the two internal walls on the right side may be disposed at different levels with respect to the thickness direction. Accordingly, a plurality of internal walls may be present in more various forms. The slope may be an acute angle formed by an internal wall with the upper surface or the lower surface of the first insulating layer 111, or an acute angle formed by an internal wall with the upper surface or the lower surface of the glass layer 110, on the cross-section penetrating through-hole h in the thickness direction.

When the wall surface of the through-hole h has at least one shifted region S as described above, dispersion of thermal and mechanical stress may be easily performed, and for example, stress occurring due to a difference in thermal expansion coefficient between glass and metal may be relieved, cracks or damage may be prevented. Also, characteristics of high-frequency signals may be improved by diversifying electrical signal paths, and reduction of electromagnetic interference (EMI) may be possible. Accordingly, signal integrity may be easily maintained. Also, by allowing heat to spread to a wide region instead of being concentrated in one place, heat generation issues may be alleviated, which may improve reliability at high temperatures. Also, an electrical contact area may increase, thereby reducing electrical contact resistance and enabling improved current transfer, which may be an important factor, especially in applications requiring high current. Also, flexibility for compensating for alignment errors during the manufacturing process may be provided, and accordingly, process bondability and manufacturing reliability may be improved. These technical effects may enable the through-via 130-1 to be effectively used in electronic devices requiring high performance and high reliability, and may also be an important factor in providing performance enhancement and mechanical stability in high-frequency or high-current applications.

Also, as the contact area between the through-via 130-1 and the glass layer 110, and the contact area between the through-via 130-1 and the first insulating layer 111 are increased, reliability of the through-via 130-1 may be improved. When the wall surface of the through-hole h has a plurality of internal walls having different slopes, the glass layer 110 may be prevented from defects such as breakage or microcracks in the glass layer 110 during the process. Accordingly, process stability may be assured.

Other descriptions may be substantially the same as those described in relation to the printed circuit board 100A, and accordingly, overlapping descriptions thereof will not be provided.

FIG. 5 is a cross-sectional diagram illustrating another example of a printed circuit board according an example embodiment.

Referring to the drawings, a printed circuit board 100B according to another example may further include a via hole v in the glass layer 110 of the printed circuit board 100A according to the above-described example. The via hole v may penetrate between an upper surface and a lower surface of the glass layer 110. The first insulating layer 111 may fill at least a portion of the via hole v. The through-hole h may be formed in a region in which the via hole v is formed. For example, the through-hole h may include a first portion h1 penetrating a region of the first insulating layer 111 filling at least a portion of the via hole v, a second portion h2 penetrating a region of the first insulating layer 111 disposed on an upper side of the via hole v, and a third portion h3 penetrating a region of the first insulating layer 111 disposed on a lower side of the via hole v. Accordingly, the via conductor 130 may be in contact with the first insulating layer 111 and may be spaced apart from the glass layer 110. The via hole v may have a shape substantially corresponding to the through-hole h, but an embodiment thereof is not limited thereto, and the holes may have a different shape if desired. The printed circuit board 100B may also have substantially the same technical effects as those described in relation to the printed circuit board 100A. Also, since the via conductor 130 is formed in the through-hole h penetrating the first insulating layer 111, adhesion may be improved and plating may be easily performed. Accordingly, reliability of the through-via 130-2 may be improved.

Other descriptions may be substantially the same as those described in relation to the printed circuit board 100A, and accordingly, overlapping descriptions thereof will not be provided.

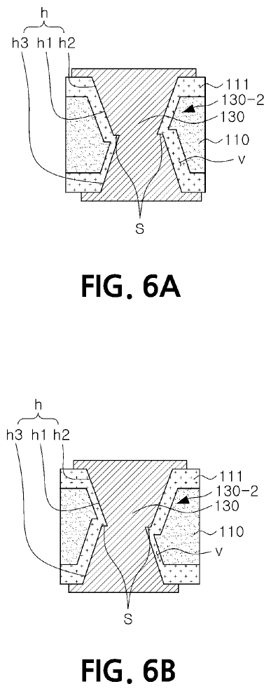

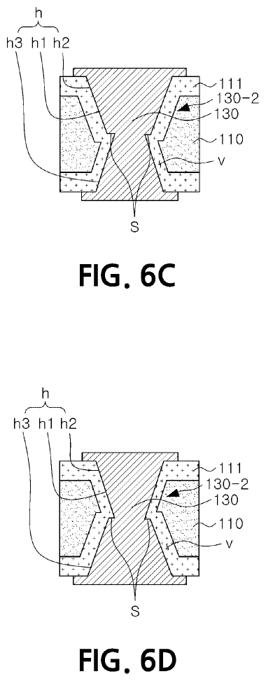

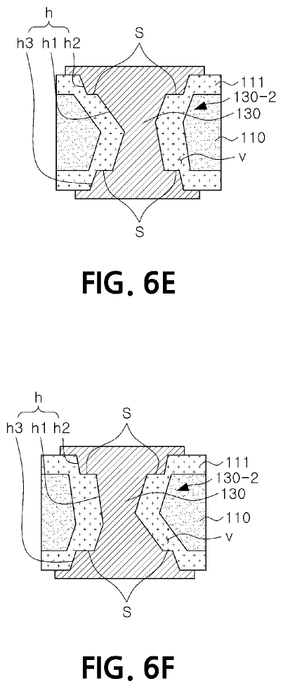

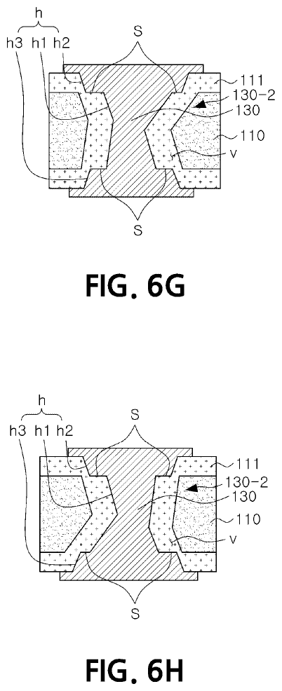

FIGS. 6A to 6H are cross-sectional diagrams illustrating various examples of a through-via formed in region B of the printed circuit board illustrated in FIG. 5.

Referring to the drawing, the wall surface of the through-hole h may have at least one shifted region S. In this view, the side surface of the through-via 130-2 may have at least one shifted region S. Also, the internal wall of the via hole v may also have at least one shifted region if desired. For example, as in FIGS. 6A to 6D, on a cross-section cutting the through-hole h in the thickness direction, each of the wall surface of the through-hole h and the wall surface of the via hole v may have at least one shifted region S at substantially the same level as the central portion of the through-hole h with respect to the thickness direction. Also, as in FIGS. 6E to 6H, on a cross-section cutting the through-hole h in the thickness direction, the wall surface of the through-hole h may also have at least one shifted region S at substantially the same level as the boundary between the upper surface and the lower surface of the glass layer 110 and the first insulating layer 111 with respect to the thickness direction. As in FIGS. 6E to 6H, in the cross-section cutting through-hole h in the thickness direction, the wall surface of through-hole h may have a plurality of internal walls having different slopes. For example, the first portion h1 of the wall surface of through-hole h may have four internal walls having different slopes. In this case, an inflection point between two internal walls on the left side and an inflection point between two internal walls on the right side may be disposed at different levels with respect to the thickness direction. Accordingly, a plurality of internal walls may be present in more various forms. The slope may be an acute angle formed by an internal wall with the upper surface or the lower surface of the first insulating layer 111 on the cross-section penetrating the through-hole h in the thickness direction, or an acute angle formed by an internal wall with the surface of the first insulating layer 111 in the shifted region S.

In this way, when the wall surface of the through-hole h has at least one shifted region S, dispersion of thermal and mechanical stress may be easily performed, and for example, stress occurring due to a difference in thermal expansion coefficient between glass and metal may be relieved, cracks or damage may be prevented. Also, characteristics of high-frequency signals may be improved by diversifying electrical signal paths, and reduction of electromagnetic interference (EMI) may be possible. Accordingly, signal integrity may be easily maintained. Also, by allowing heat to spread to a wide region instead of being concentrated in one place, heat generation issues may be alleviated, which may improve reliability at high temperatures. Also, an electrical contact area may increase, thereby reducing electrical contact resistance and enabling improved current transfer, which may be an important factor, especially in applications requiring high current. Also, flexibility for compensating for alignment errors during the manufacturing process may be provided, and accordingly, process bondability and manufacturing reliability may be improved. These technical effects may enable the through-via 130-2 to be effectively used in electronic devices requiring high performance and high reliability, and may also be an important factor in providing performance enhancement and mechanical stability in high-frequency or high-current applications.

Also, since the contact area between the through-via 130-2 and the first insulating layer 111 is widened, reliability of the through-via 130-2 may be improved. When the wall surface of the through-hole h has a plurality of internal walls having different slopes, defects in the glass layer 110, such as breakage of the glass layer 110 or microcracks in the glass layer 110 during the process may be prevented. Accordingly, process stability may be assured.

Other descriptions may be substantially the same as those described in relation to the printed circuit boards 100A and 100B, and accordingly, overlapping descriptions thereof will not be provided.

According to the aforementioned example embodiments, a printed circuit board which may be advantageous for warpage control and may easily implement a microcircuit therein may be provided.

Also, a printed circuit board which may reduce the number of processes and costs may be provided.

Also, a printed circuit board which may assure process stability and a through-via therein may have improved reliability may be provided.

In the present disclosure, the term “covering” may include covering entirely and also covering at least a portion, and may also include covering directly and also covering indirectly. Also, the term “filling” may include filling completely and also filling roughly, and may include, for example, the presence of some gaps or voids. Also, the expression of surrounding may include not only the case of completely surrounding, but also the case of surrounding a portion and the case of roughly surrounding. Also, exposing may include completely exposing, and also partially exposing, and exposure may indicate being exposed from embedding the corresponding component. For example, opening exposing a pad may indicate exposing the pad from the resist layer, and a surface treatment layer may be disposed on the exposed pad.

In the present disclosure, being disposed in a through-portion or a through-hole may include the configuration in which an object is disposed entirely in the through-portion or a through-hole, and also the configuration in which an object partially protrudes to the upper side or the lower side on the cross-section. For example, when a component is disposed in a through-portion or a through-hole on a plane, broader interpretation may be possible.

In the present disclosure, process errors, positional deviations, and measurement errors occurring in the manufacturing process may be included. For example, the notion that the line width, distance, thickness, and height are substantially the same may include case in which the elements are completely the same in numerical sense, and also case in which the elements may have similar values. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances. Also, the notion of “having substantially a predetermined shape” may include case of having almost the same shape and also having a similar shape.

In the present disclosure, the same insulating material may indicate that the materials are completely the same insulating material, but insulating materials of the same type are included. Accordingly, the composition of the insulating material may be substantially the same, but the specific composition ratios thereof may be slightly different.

The terms “lower side,” “lower portion,” “lower surface,” and the like, may be used to refer to a surface formed in a downward direction with reference to a cross-section in the diagrams for ease of description, the terms “upper side,” “upper portion,” “upper surfaces,” and the like, may be used to refer to a surface formed in an upward direction, and the terms “side portion,” “side surface,” and the like, may be used to refer to a surface formed taken in the direction perpendicular to a upper surface and lower surface. The terms, however, may be defined as above for ease of description, and the scope of right of the example embodiments is not particularly limited to the above terms.

In the example embodiments, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

In the example embodiments, a thickness, width, length, pitch, depth, or the like, may be measured using a scanning microscope or optical microscope based on a cross-section of a printed circuit board polished or cut out. The cross-section may be a vertical cross-section or a horizontal cross-section, and each value may be measured based on the required cross-section. For example, the width of the upper end and/or lower end of a via may be measured on a cross-section taken along the central axis of the via. In this case, when the values are not constant, the values may be determined as the average of the values measured at arbitrary five points.

In the example embodiments, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in one example embodiment are not described in the other example embodiment, the description may be understood as relevant to the other example embodiment unless otherwise indicated.

An expression used in the singular encompasses the expression of the plural, unless it has a clearly different meaning in the context.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a glass layer;
a first insulating layer covering each of an upper surface and a lower surface of the glass layer;
a first conductor layer disposed on an upper surface of the first insulating layer;
a second conductor layer disposed on a lower surface of the first insulating layer; and
a through-hole penetrating between the first and second conductor layers, and a through-via including a via conductor disposed in the through-hole and connected to the first and second conductor layers,
wherein a wall surface of the through-hole has at least one shifted region.

2. The printed circuit board of claim 1,
wherein, on a cross-section cutting the through-hole in a thickness direction, a width of the through-hole at an upper end connected to the first conductor layer and a width at a lower end connected to the second conductor layer are greater than a width at a central portion of the through-hole, and
wherein the central portion of the through-hole is disposed between the upper surface and the lower surface of the glass layer.

3. The printed circuit board of claim 2, wherein the wall surface of the through-hole has the at least one shifted region at substantially the same level as the central portion of the through-hole with respect to the thickness direction.

4. The printed circuit board of claim 2, wherein the wall surface of the through-hole has the at least one shifted region at substantially the same level as a boundary between the upper surface of the glass layer and the first insulating layer, and a boundary between the lower surface of the glass layer and the first insulating layer with respect to the thickness direction.

5. The printed circuit board of claim 2, wherein the wall surface of the through-hole has a plurality of internal walls having different slopes.

6. The printed circuit board of claim 5,
wherein, on the cross-section cutting the through-hole in the thickness direction, a portion penetrating between the upper surface and the lower surface of the glass layer on the wall surface of the through-hole has four internal walls having different slopes, and
wherein an inflection point between two internal walls on a left side of the cross-section and an inflection point between two internal walls on a right side of the cross-section among the four internal walls are disposed at different levels with respect to the thickness direction.

7. The printed circuit board of claim 1, wherein the first insulating layer further covers a side surface of the glass layer.

8. The printed circuit board of claim 7, further comprising:
a frame having a through-portion,
wherein the glass layer is disposed at least a portion in the through-portion,
wherein the first insulating layer further covers an upper surface and a lower surface of the frame, and
wherein the first insulating layer is disposed in at least a portion of the through-portion.

9. The printed circuit board of claim 1,
wherein the through-hole includes a first portion penetrating the glass layer, a second portion penetrating a region of the first insulating layer covering the upper surface of the glass layer, and a third portion penetrating a region of the first insulating layer covering the lower surface of the glass layer.

10. The printed circuit board of claim 9,
wherein at least a portion of the via conductor is in contact with the glass layer, and
wherein at least another portion of the via conductor is in contact with the first insulating layer.

11. The printed circuit board of claim 1,
wherein the glass layer has a via hole penetrating the glass layer,
wherein the first insulating layer fills at least a portion of the via hole, and
wherein the through-hole includes a first portion penetrating a region of the first insulating layer filling at least a portion of the via hole, a second portion penetrating a region of the first insulating layer disposed on an upper side of the via hole, and a third portion penetrating a region of the first insulating layer disposed on a lower side of the via hole.

12. The printed circuit board of claim 1, wherein the via conductor is in contact with the first insulating layer and is spaced apart from the glass layer.

13. The printed circuit board of claim 1, further comprising:
a second insulating layer disposed on the upper surface of the first insulating layer and covering at least a portion of the first conductor layer;
a third insulating layer disposed on the lower surface of the first insulating layer and covering at least a portion of the second conductor layer;
a third conductor layer disposed on an upper surface of the second insulating layer;
a fourth conductor layer disposed on a lower surface of the third insulating layer;
a first connection via penetrating at least a portion of the second insulating layer and connecting at least a portion of the first conductor layer and at least a portion of the third conductor layer to each other; and
a second connection via penetrating at least a portion of the third insulating layer and connecting at least a portion of the second conductor layer and at least a portion of the fourth conductor layer to each other.

14. The printed circuit board of claim 13, further comprising:
a first passivation layer disposed on an upper surface of the second insulating layer and having a plurality of first openings each exposing at least a portion of the third conductor layer; and
a second passivation layer disposed on a lower surface of the third insulating layer and having a plurality of second openings each exposing at least a portion of the fourth conductor layer.

15. A printed circuit board, comprising:
an insulating layer;
a glass layer embedded in the insulating layer;
a first conductor layer disposed on an upper surface of the insulating layer;
a second conductor layer disposed on a lower surface of the insulating layer; and
a through-via penetrating the insulating layer and the glass layer between the first and second conductor layers and connecting the first and second conductor layers to each other,
wherein a side surface of the through-via has at least one shifted region.

16. The printed circuit board of claim 15, further comprising:
a frame having at least a portion buried in the insulating layer, and including a through-portion in which at least a portion of the glass layer is disposed,
wherein the insulating layer is disposed in at least a portion between the frame and the glass layer.
